(19) United States
(12) Patent Application Publication
(10) Pub. No.: US 2025/0096535 A1
(43) Pub. Date: Mar. 20, 2025

(54) VCSEL FOR EMITTING LASER LIGHT

(71) Applicant: TRUMPF Photonic Components GmbH, Ulm (DE)

(72) Inventors: Simeon Renz, Illerkirchberg (DE); Stephan Gronenborn, Aachen (DE); Roman Körner, Lonsee (DE); Xi Gu, Veldhoven (NL)

(21) Appl. No.: 18/967,697

(22) Filed: Dec. 4, 2024

Related U.S. Application Data
(63) Continuation of application No. PCT/EP2023/065086, filed on Jun. 6, 2023.

(30) Foreign Application Priority Data
Jun. 13, 2022 (DE) 10 2022 114 856.4

(51) Int. Cl. H01S 5/42; H01S 5/042; H01S 5/183

(52) U.S. Cl. CPC H01S 5/423; H01S 5/04256; H01S 5/18347

(57) ABSTRACT

A VCSEL for emitting laser light includes a main element which has a mesa portion. The mesa portion includes a stack of different layers stacked in a stacking direction. An emission region is formed on a top surface of the mesa portion. Laser light generated in an active layer in the stack emerges from the emission region. Electrical contacts for feeding electrical energy into the active layer are provided on the main element. At least one side portion of an electrical contact of the electrical contacts is arranged on a side surface of the main element. The side surface is oriented transversely with respect to the layers.

### CROSS REFERENCE TO RELATED APPLICATIONS

This application is a continuation of International Application No. PCT/EP2023/065086 (WO 2023/241993 A1), filed on Jun. 6, 2023, and claims benefit to German Patent Application No. DE 10 2022 114 856.4, filed on Jun. 13, 2022. The aforementioned applications are hereby incorporated by reference herein.

### FIELD

Embodiments of the present invention relate to a vertical cavity surface emitting laser (VCSEL) for emitting laser light. Embodiments of the present invention also relate to a VCSEL array having such VCSELs as well as to an electrical circuit board having such a VCSEL and/or a VCSEL array. Embodiments of the present invention further relate to a method for manufacturing such a VCSEL.

### BACKGROUND

VCSELs are known that have electrical contacts for feeding in electrical energy. These electrical contacts are mounted on the upper side and/or underside of the VCSEL (vertical-cavity surface-emitting laser). This makes efficient soldering, for example using a wave soldering process, impossible.

For example, U.S. Pat. No. 6,678,292B2 shows a VCSEL that has both p-type and n-type contacts on top of the emitting surface. The contacts are connected to an electrical circuit board via wires. This makes a soldering process suitable for mass production impossible.

The problem solved by the present invention consists in providing a VCSEL which can be mounted on an electrical circuit board by a soldering process suitable for mass production.

### SUMMARY

Embodiments of the present invention provide a VCSEL for emitting laser light. The VCSEL includes a main element which has a mesa portion. The mesa portion includes a stack of different layers stacked in a stacking direction. An emission region is formed on a top surface of the mesa portion. Laser light generated in an active layer in the stack emerges from the emission region. Electrical contacts for feeding electrical energy into the active layer are provided on the main element. At least one side portion of an electrical contact of the electrical contacts is arranged on a side surface of the main element. The side surface is oriented transversely with respect to the layers.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a VCSEL with electrical contacts arranged both on a side surface and on a top surface of the main element according to some embodiments;

FIG. 2 shows a VCSEL with electrical contacts, wherein at least one electrical contact is arranged only on one side surface of the main element, according to some embodiments;

FIG. 3 shows a plan view of a VCSEL according to FIG. 1 or 2, according to some embodiments;

FIG. 4 shows a plan view of a VCSEL array with VCSELs according to FIG. 1 or 2, according to some embodiments;

FIGS. 5-9 show a first embodiment of a method for producing side portions on side surfaces of main elements;

FIGS. 10-15 show a second embodiment of a method for producing side portions on side surfaces of main elements; and

FIG. 16A and FIG. 16B show a schematic representation of an electrical circuit board with two different arrangement variants of the VCSEL according to some embodiments.

### DETAILED DESCRIPTION

Embodiments of the present invention provide a VCSEL for emitting laser light with a main element which has a mesa portion which has a stack of different layers stacked in a stacking direction, wherein an emission region is formed on the top surface of the mesa portion, from which emission region the laser light generated in an active layer in the stack emerges, wherein electrical contacts for feeding electrical energy into the active layer are provided on the main element, wherein at least one side portion of an electrical contact is arranged on a side surface of the main element, wherein the side surfaces are oriented transversely with respect to the layers.

The main element is formed by layers stacked on top of each other. The mesa portion forms the part of the main element which emits the laser light and on the surface of which the emission region is arranged. The surface comprises the top surface forming the outer side of a Bragg mirror of a pair of Bragg mirrors between which the active layer is arranged.

The electrical contacts include metal and preferably cover a part of the side surface of the main element.

Advantageously, the top surface is oriented perpendicular to the stacking direction. The side surfaces can also be oriented approximately perpendicularly or form an angle with the top surface that is greater than 90°.

It is preferred to mount an insulating layer between the side portion of the electrical contact and the side surface. The insulating layer can also act as an adhesive layer, ensuring that the electrical contact adheres to the side surface.

In a special development, the electrical contact extends from its side portion to the upper side of the main element. The electrical contact can cover part of the top surface with an upper portion.

Preferably, the side portions of electrical contacts, which are designed as a cathode or an anode, can be mounted on preferably a common side surface of the mesa portion. This allows both the supply and the discharge of electrical energy in the VCSEL to be realized through connections on a side surface, which can, for example, be placed on an electrical solder contact of a conductor track on an electrical circuit board. For this purpose, the VCSEL can be tilted such that the beam axis of the laser light is oriented parallel to the extension plane of the electrical circuit board, wherein the electrical contacts are preferably arranged between the electrical circuit board and the VCSEL.

Alternatively or additionally, the electrical contacts can be mounted on different sides of the VCSEL. An electrical contact of the cathode can be arranged on an opposite side to the electrical contact of the anode.

In order to achieve a low-stress transition between an upper portion of the electrical contact on the top surface and the side portion, a chamfer or a rounded portion can be formed at a transition region between the side surface and the top surface, wherein a portion of the electrical contact is arranged on the transition region. The transition region can be created by an etching step, e.g., by a combination of an isotropic and an anisotropic etching step.

A solder barrier may be formed on the upper portion of the electrical contact on the top surface of the main element to prevent solder from flowing from the side portion to the emission region. The solder barrier can be mounted on the upper portion of the electrical contact in an additional step after the electrical contact has been applied.

In a further exemplary embodiment, at least one electrical contact is formed only on the side surface, without extending to the top surface. This prevents the solder from flowing onto the surface of the main element because the metallized portion of the electrical contact does not reach the top surface.

Furthermore, a VCSEL array can be formed by means of the VCSEL and has at least two main elements, each of which has at least one side portion of an electrical contact on its side surfaces. Side portions can be mounted on side surfaces that are oriented in opposite directions. Alternatively, side portions can be arranged on side surfaces that are oriented in the same direction.

Furthermore, an electrical circuit board with a VCSEL and/or a VCSEL array can be provided, wherein the VCSEL or the VCSEL array rest on a side surface on the electrical circuit board so that the side portion can be soldered onto a solder contact of the electrical circuit board.

Furthermore, a method for producing a VCSEL is proposed in which main elements are arranged on a wafer, wherein a trench is formed next to a main element, wherein the trench creates a side surface on a main element, wherein the side surfaces are provided with a side portion of an electrical contact assigned to a mesa portion of the main element. An insulating layer, which contains silicon for example, can first be applied, to which a metallic adhesive layer, which contains titanium for example, is applied. The electrical contact, which can consist of gold, can be applied to the adhesive layer.

Advantageously, the trench can be formed between two main elements, wherein the side surfaces are coated, wherein the two main elements are separated from one another by making a separating cut along the trench, which leaves the side portions on the side surfaces. In particular, the trench is not completely filled.

In an alternative embodiment, the trench can be completely filled with a metal so that the side surface is also covered with a metal. Alternatively, only one side surface in the trench can be coated.

Preferably, after filling the trench, a portion adjacent to the trench that reaches to the trench can be removed so as to expose the main element with the side surface covered with the metal so that the metal forming the side portion can be contacted. As a result, the portion next to the trench is removed and the side portion is exposed.

Exemplary embodiments are described below with reference to the associated drawings. Direction indications in the following explanation are to be understood according to the reading direction of the drawings. The position indications of above and below are to be understood according to the drawings.

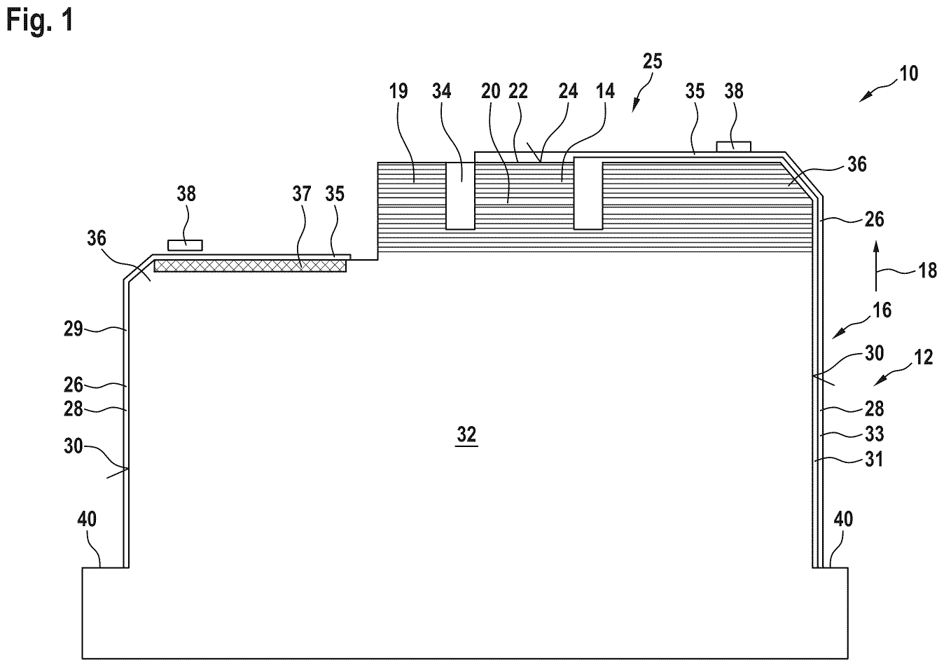

FIG. 1 shows a VCSEL (vertical-cavity surface-emitting laser) 10, which emits laser light. The VCSEL 10 has a main element 12 which has a mesa portion 14. The main element 12 and thus also the mesa portion 14 are made from a stack 16 of different layers 19 stacked in a stacking direction 18.

The layers 19 fulfill different functions, so the mesa portion 14 has a pair of Bragg mirrors between which an active layer 20 is arranged. The active layer 20 generates photons that emerge as laser light from an emission region 22. The emission region 22 is on the surface of the mesa portion 14. The surface comprises a top surface 24 on the upper side 25 of the VCSEL, which is the outer side of the upper Bragg mirror.

Electrical contacts 26 for feeding electrical energy into the active layer 20 are provided on the main element 12. The electrical contacts 26 are designed as an anode 33 and a cathode 29 and have metallic portions. Furthermore, at least one of the electrical contacts 26 has a side portion 28 which is arranged on a side surface 30 of the main element 12. The side surface 30 is oriented on the main element 12 transverse to the top surface 24. The side surface 30 is preferably oriented perpendicular to the top surface 24. Alternatively, at least a part of the side surface 30 may form an angle with the top surface 24 that is greater than 90°.

The electrical contacts 26 preferably include gold, which is applied in each case to a titanium-containing adhesive layer, wherein the electrical contacts 26 covers only a part of the side surface 30 of the main element 12 by at least one side portion 28. The side portions 28 can be strip-like. Only one side portion 28 can be provided per main element 12. The titanium-containing adhesive layer is applied to an insulating layer 31.

The main element 12 of the VCSEL 10 has a substrate 32 on which the stack 16 is arranged. Purely by way of example, the mesa portion 14 is separated from the remaining part of the main element 12 by slots 34. A chamfer or a rounded portion is formed at a transition region 36 between the top surface 24 on the upper side 25 of the main element 12 and the side surface 30. The slots 34 are filled with the material that forms the insulating layer 31. The insulating layer 31 below the titanium-containing adhesive layer is connected continuously to the material in the slots 34.

The upper portion 35 of the electrical contact 26 is arranged on the top surface 24. The electrical contact 26 extends from the top surface 24 to the side surface 30, wherein a portion of the electrical contact 26 is arranged on the transition region 36 such that the portion is arranged between the upper portion 35 and the side portion 28.

On the upper side 25, solder barriers 38 are arranged on the electrical contact 26 and prevent solder from flowing from the side portion 28 to the emission region 22 on the top surface 24 of the main element 12, e.g., owing to the surface tension of the solder. The solder barrier 38 is deposited on the electrical contact 26 by an additional step.

The exemplary VCSEL 10 in FIG. 1 has the substrate 32 on which the stack 16 is arranged. The stack 16 does not cover the entire substrate 32, so a step is formed. The top surface 24 is formed on the higher level of the step. An upper portion 35 of a cathode 29 is arranged on the lower level of the step, and an ohmic contact 37 is formed between the upper portion 35 of the cathode 29 and the substrate 32. The electrical contact 26 extends from the upper portion 35 to a side surface 30 on the main element 12, wherein a portion of the electrical contact 26 covers a transition region 36 formed on the substrate 32.

Preferably, an anode 33 is arranged as an electrical contact 26 on a side of the VCSEL 10 opposite the cathode 29. The side portion 28 extends along a side surface 30 that extends from the substrate 32 to the stack 16. The transition region 36 is formed on the stack 16. The upper portion 35 extends to the emission region 22. A shoulder 40 is formed on the underside of the substrate 32. The shoulder 40 creates a corner between the side surface 30 and a surface of the shoulder 40. The side portion 28 reaches to the corner.

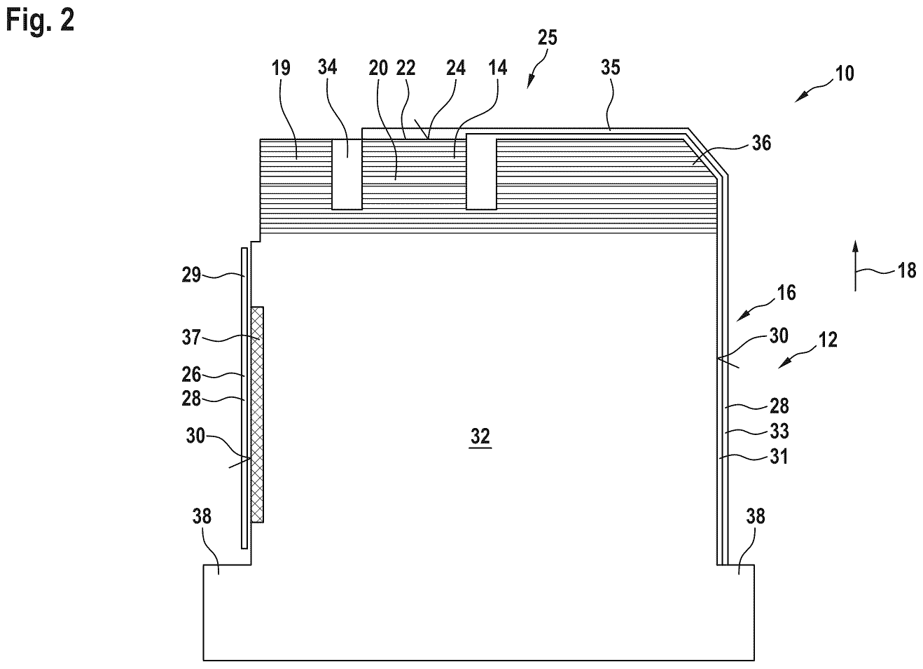

FIG. 2 shows a further exemplary embodiment in which, purely by way of example, the cathode 29 is mounted on the side surface 30 of the main element 12 in such a way that it does not extend to the upper side 25 of the main element 12. The cathode 29 is formed by the side portion 28, wherein no upper portion is present. An ohmic contact 37 is arranged on the side surface 30 of the main element 12, and the ohmic contact 37 can only be formed on the substrate 32. Preferably, the side portion 28 does not extend to the stack 16. The cathode 28 is designed according to the exemplary embodiment of FIG. 1.

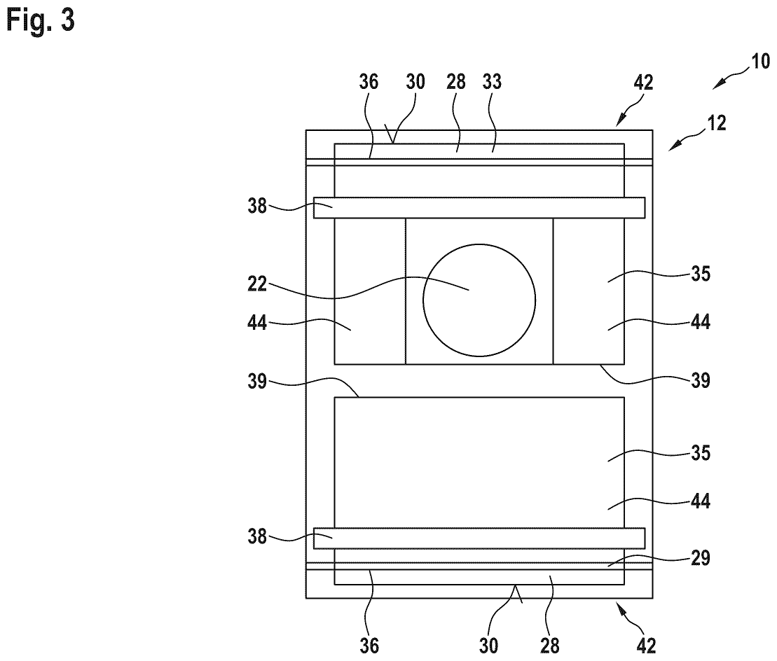

FIG. 3 shows a plan view of a VCSEL 10, which has a side portion 28 on opposite sides 42. The side portions 28 are structured according to FIG. 1 or FIG. 2. The anode 33 and the cathode 29 extend from the upper side 25 to the side surfaces 30. An elongated solder barrier 38 is arranged on the upper portion 35. The solder barrier 38 may contain titanium oxide or silicon nitride. Furthermore, a longitudinal notch can be provided along the longitudinal extension of the solder barrier 38. Preferably, the solder barrier 38 is arranged closer to the transition region 36 than to an opposite end 39 of the upper portion 35. Furthermore, test contact surfaces 44 can be provided on the upper portion 35 so that after the VCSEL 10 has been manufactured in a factory, a test for the functionality of the VCSEL 10 can be carried out in the factory.

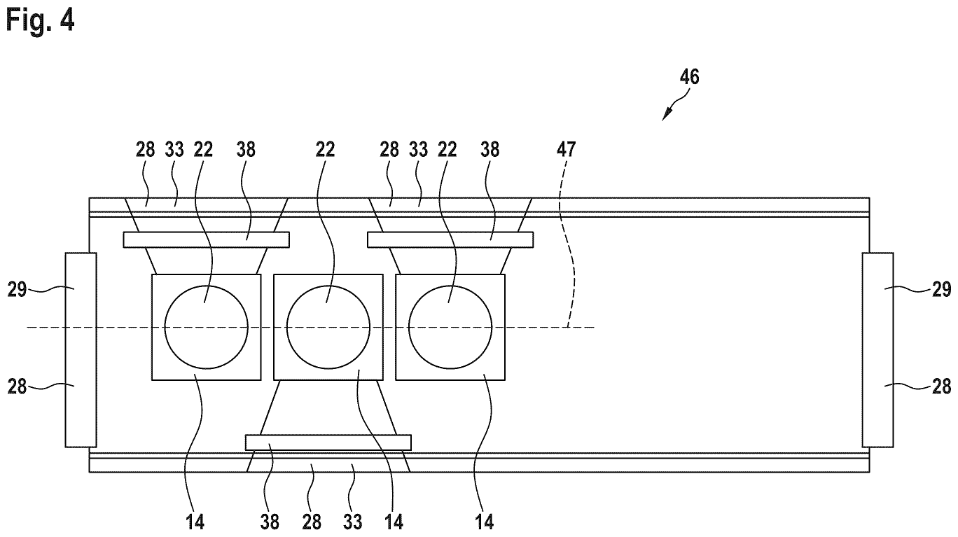

FIG. 4 shows a VCSEL array 46 which has a plurality of emission regions 22. For each emission region 22, a mesa portion 14 or a separate main element 12 can be provided, which are arranged on the VCSEL array 46. Side portions 28 are formed on the side surfaces 30 of the individual main elements 12 or mesa portions 14. In this case, anodes 33 are arranged as side portions 28 in an alternating manner on oppositely oriented side surfaces 28. Purely by way of example, three main elements 12 are arranged on the VCSEL array 46, which are arranged along an imaginary line. The side portions 28 are arranged on opposite sides with respect to the imaginary line. The side portions 28 of the two outer main elements 12 are arranged on the same side with respect to the imaginary line 47. The middle main element 12 has a side portion 28 which is oriented in the opposite direction. The cathodes 29 of the VCSEL array 46 are arranged on opposite sides of the VCSEL array 46, which are not assigned to a single main element 12. Purely by way of example, the cathodes 29 are arranged at the longitudinal ends of the VCSEL array 46.

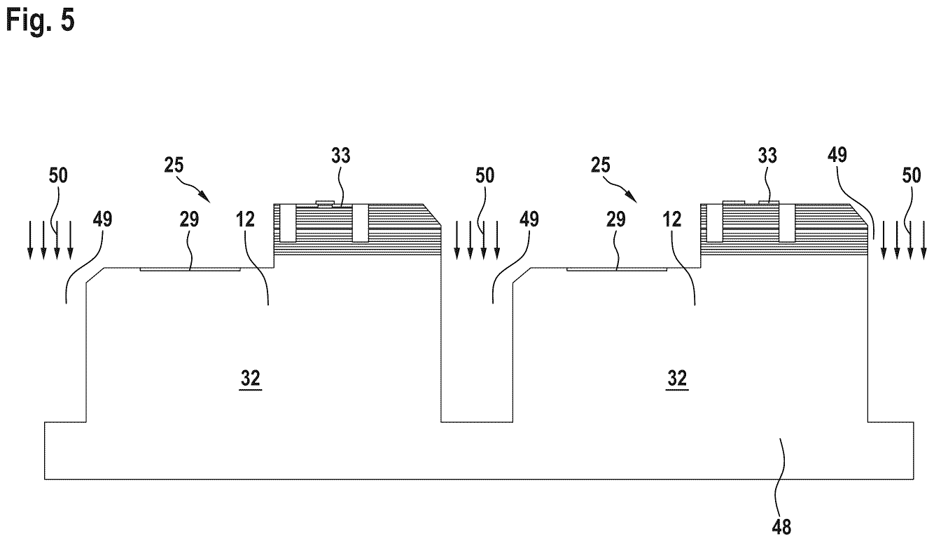

FIGS. 5 to 9 show a first exemplary embodiment of a method for producing a VCSEL 10 or a VCSEL array 46.

FIG. 5 shows that main elements 12 are formed on a wafer 48 in a lithography-etching step, which are separated by trenches 49. The etching direction 50 is shown by arrows. Two main elements 12 are shown by way of example. The ohmic contacts 37 on the upper side 25 for the anode 33 and the cathode 29 are produced by metallization.

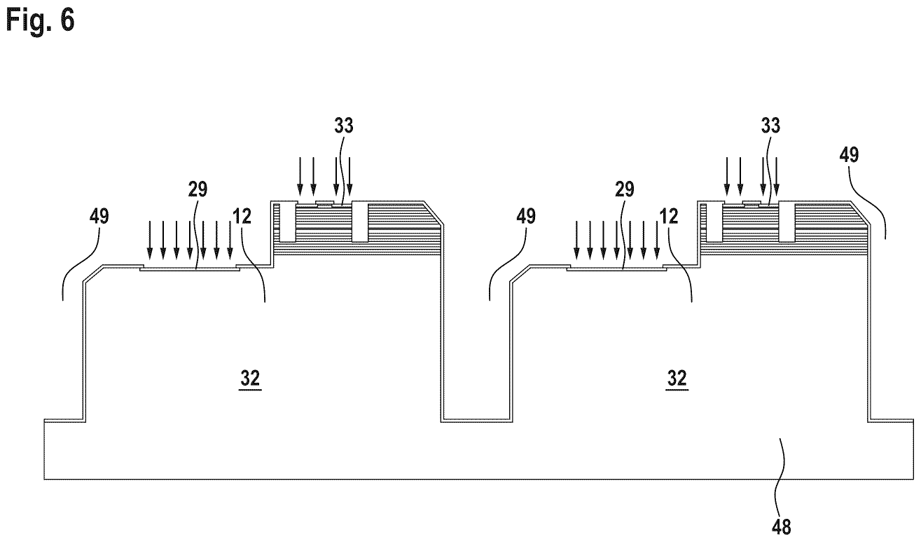

FIG. 6 shows a passivation step with subsequent exposure of the anode 33 and the cathode 29 by etching. Passivation is achieved, for example, by a silicon nitride coating. On the upper side 25, the metallized portions are exposed by an etching step.

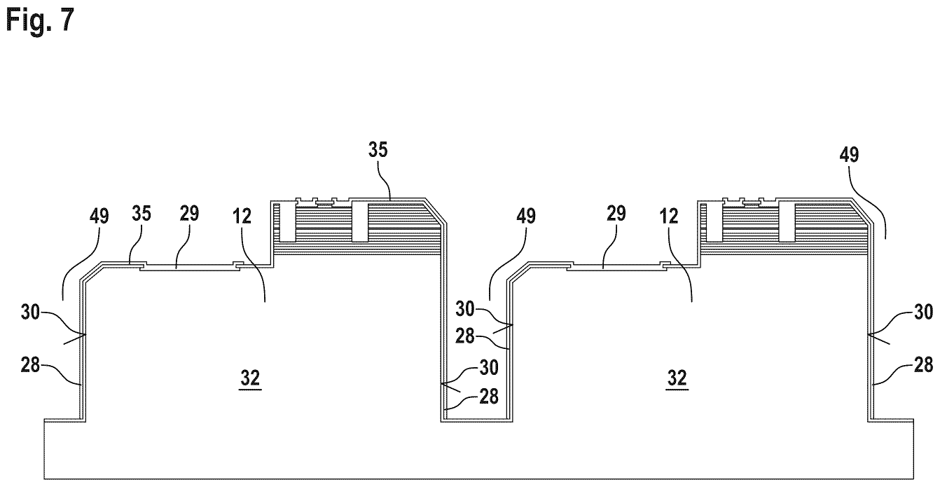

In FIG. 7, the side surfaces 30 in the trenches 49 are coated with a metal such as gold and form the side portions 28 of the cathode 29 and anode 33. The corresponding upper portions 35 are also formed. By creating a seed layer applied by sputtering or an atomic layer deposition method, an adhesive layer for a metallized portion can be provided. The cathode 29 and the anode 33 can then be produced by the metallized portion. The final shape of the electrical contacts can be predetermined by a lithography mask.

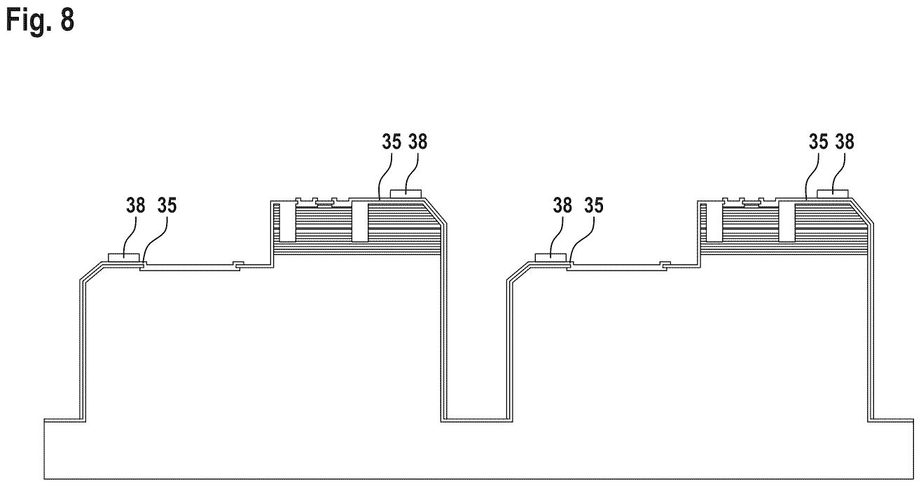

In FIG. 8, the solder barrier 38 is additionally applied, which is arranged on the upper portion 35.

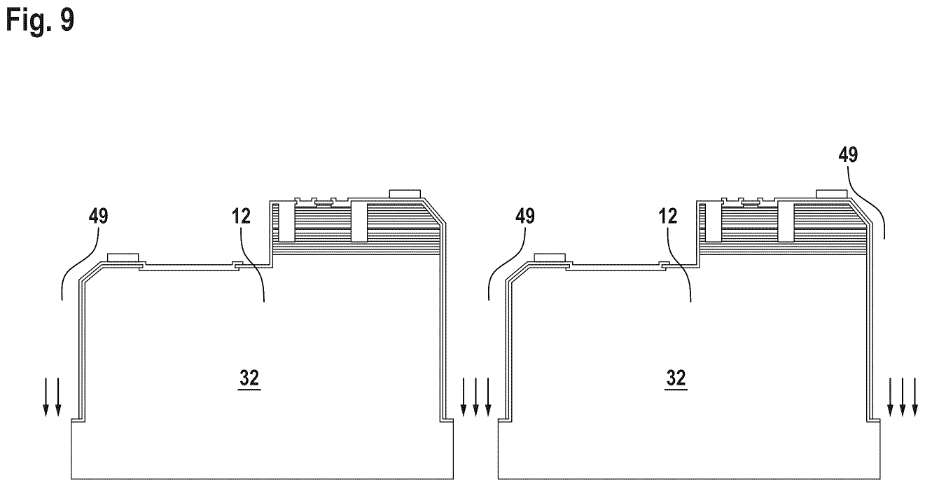

In FIG. 9, the trench 49 is further deepened by a plasma etching step using a lithography mask until the substrate 32 is severed by this separating step so that the main elements 12 are separated from one another.

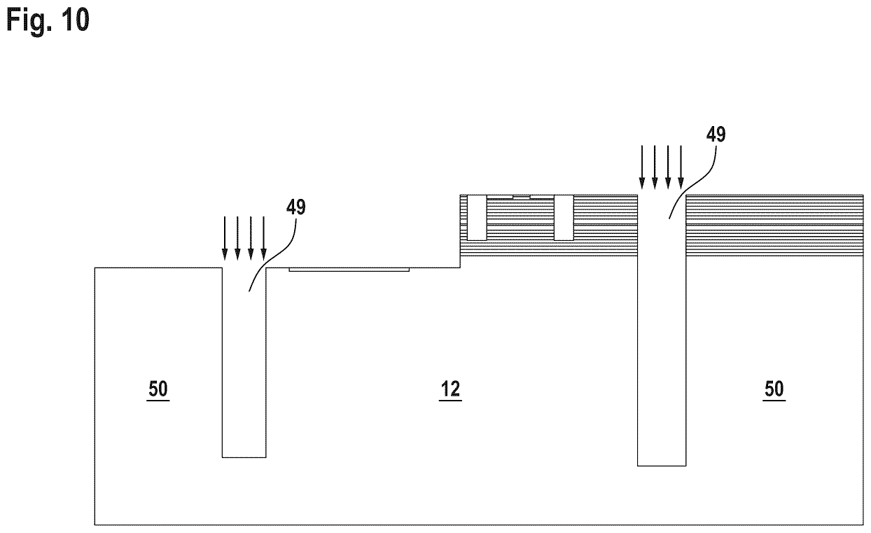

A second exemplary embodiment of the method for producing a VCSEL 10 or a VCSEL array 46 is shown in FIGS. 10 to 15.

In FIG. 10, a main element 12 is delimited by etched trenches 49, which are defined by a lithography mask. In addition to the trenches 49, a portion 50 is formed which is sacrificed in the subsequent steps. The portion 50 reaches to the trench 49.

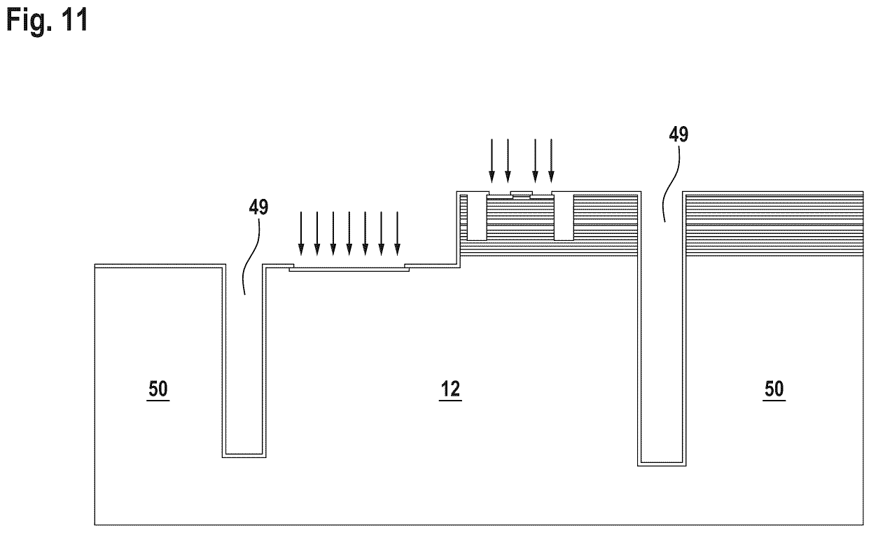

In FIG. 11, passivation is applied according to FIG. 6 and an etching step exposes metallic contacts that were previously made.

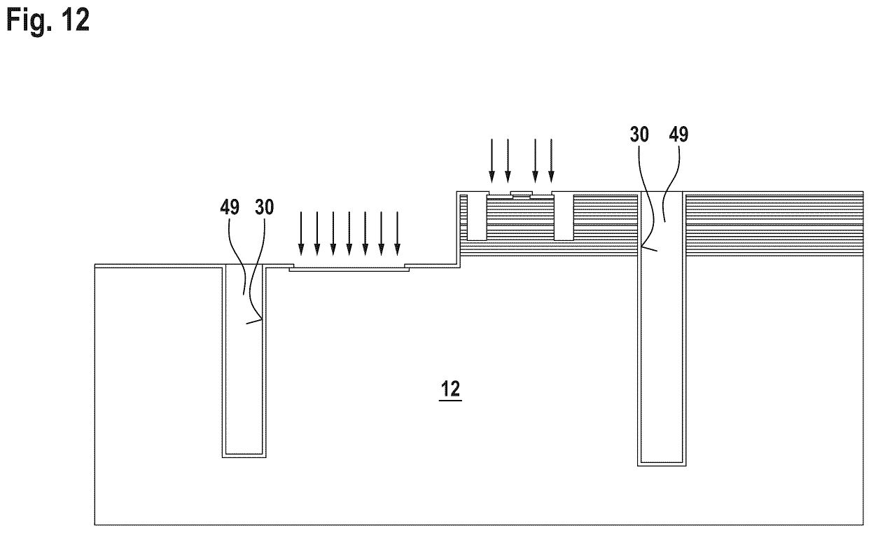

According to FIG. 12, the trenches 49 are completely filled with a metal such as gold.

As a result, the side surfaces 30 are covered by the metal.

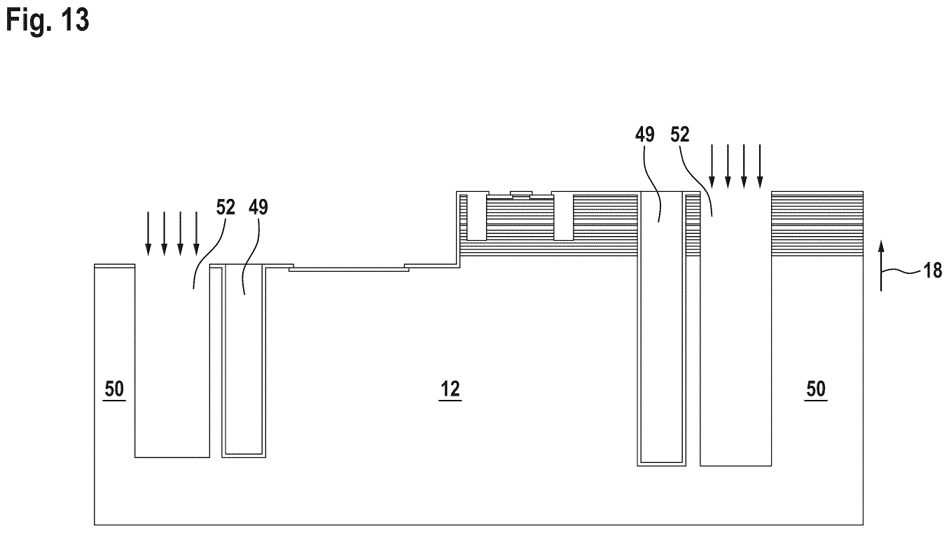

After the trenches 49 are completely filled with metal and the side surfaces 30 are covered, an isotropic etching step is carried out along the axis of the stacking direction 18 according to FIG. 13, such that openings 52 perpendicular to the layers of the stack are created in the portion 50.

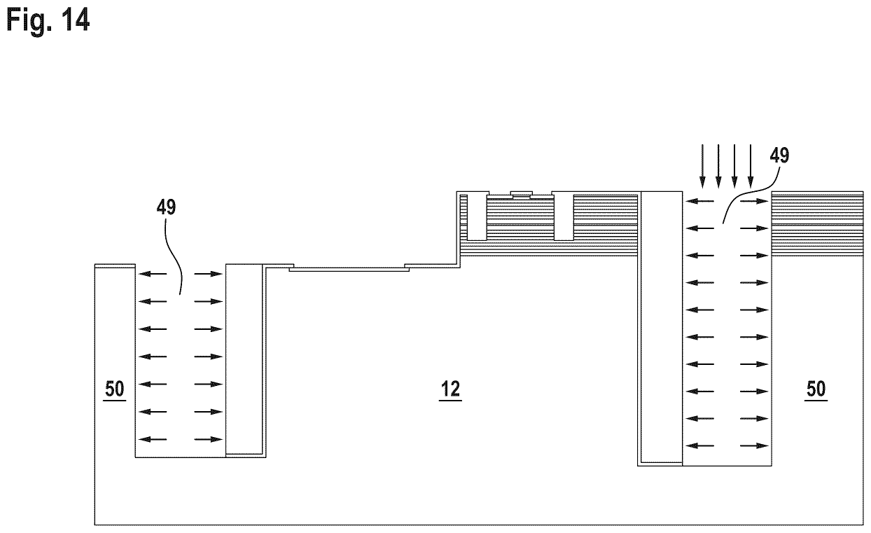

Subsequently, an anisotropic etching step is performed as shown in FIG. 14, which enlarges the openings 52. Gallium arsenide and silicon nitride can be etched anisotropically.

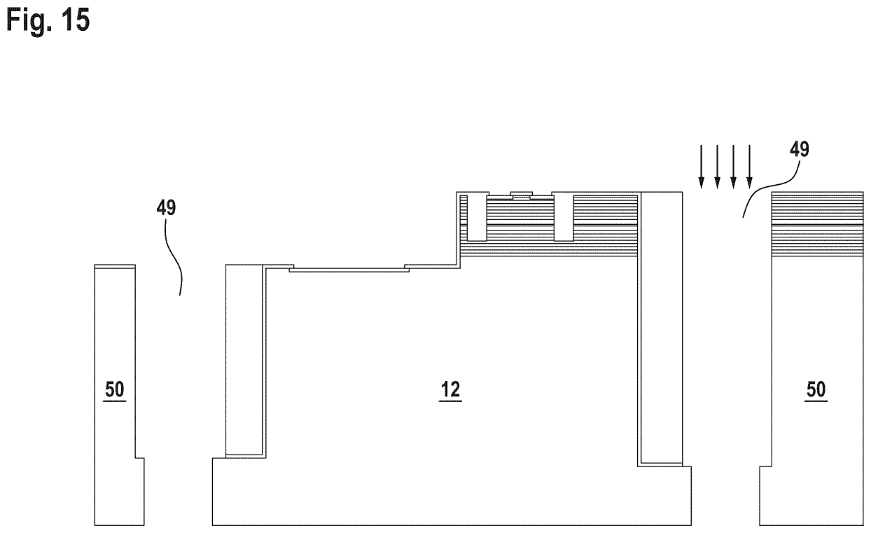

Finally, a separating step is carried out by plasma etching according to FIG. 15, which corresponds to the step in FIG. 9.

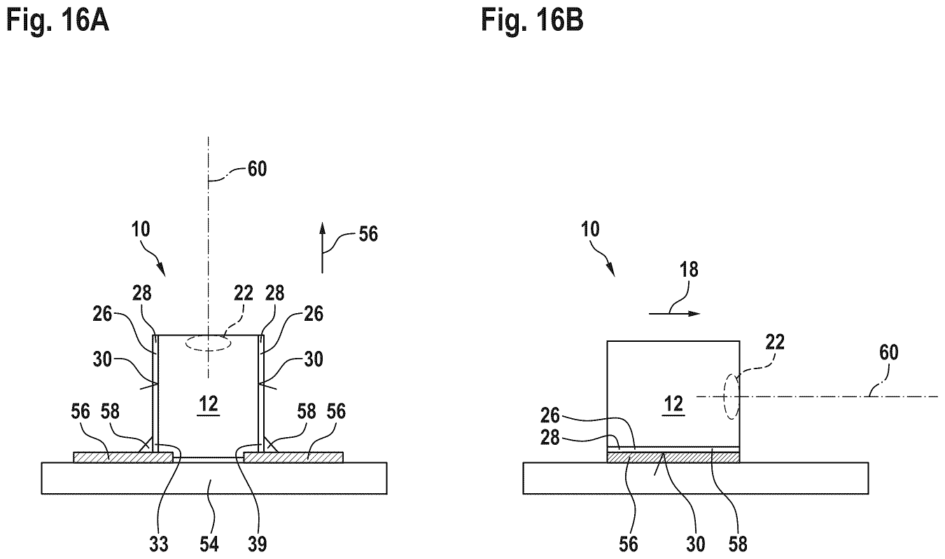

FIG. 16 shows a schematic representation of an electrical circuit board 54 on which two VCSELs 10 are arranged.

FIG. 16A shows a VCSEL 10 which corresponds to an exemplary embodiment of the preceding figures. In this exemplary embodiment, a laser axis 60, along which the laser light substantially propagates, is oriented parallel to the axis of the stacking direction 18. In this case, the laser axis 60 is oriented perpendicular to the electrical circuit board 54. The emission region 22 is arranged on a side of the VCSEL 10 opposite the electrical circuit boards 54. The side portions 28 of the electrical contacts 26 are positioned on the side surfaces 30 and are oriented perpendicular to the main extension direction of the electrical circuit board 54. The side portions 28 are positioned in the region of electrical conductor tracks 56 to which they are soldered. A cathode 29 is soldered to a solder contact of a conductor track 56 assigned to the cathode 29. The anode 33 is soldered to a solder contact which is part of a conductor track 56 which is assigned to a conductor track 56 assigned to the anode 33. The solder forms a meniscus-like solder joint 58 in the corner between the conductor track 56 and the side portion 28. The solder joint 58 can be concave in the form of a groove as in FIG. 16A or alternatively convex. The side portions 28 are arranged purely by way of example on opposite sides of the VCSEL 10. Alternatively, they can be arranged on the same side surfaces 30 of the VCSEL 10 or on side surfaces separated by a common corner.

In the exemplary embodiment of FIG. 16B, the VCSEL 10 is oriented such that the laser axis 60 is oriented parallel to the main extension plane of the electrical circuit board 54. The electrical contacts 26 are positioned between the conductor track 56 and the main element 12 of the VCSEL 10, wherein the solder preferably forms a flat solder joint 58. According to the tilted position of the VCSEL 10 and the stacking direction 18 which is now oriented parallel to the main extension plane of the electrical circuit board 54, the laser light from the emission region 22 propagates substantially parallel to the electrical circuit board 54. In an alternative of FIG. 16B, the side portions 28 can also be mounted on side surfaces 30 of the VCSEL 10 that are oriented perpendicular to the main extension plane of the electrical circuit board 54, such that a concave or convex solder joint 58 can be created in the corner between a conductor track 56 and a side portion 28.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A VCSEL for emitting laser light, the VCSEL comprising:
a main element which has a mesa portion, the mesa portion comprising a stack of different layers stacked in a stacking direction, wherein an emission region is formed on a top surface of the mesa portion, wherein laser light generated in an active layer in the stack emerges from the emission region, wherein electrical contacts for feeding electrical energy into the active layer are provided on the main element, wherein at least one side portion of an electrical contact of the electrical contacts is arranged on a side surface of the main element, wherein the side surface is oriented transversely with respect to the layers.

2. The VCSEL according to claim 1, wherein the top surface is oriented perpendicular to the stacking direction.

3. The VCSEL according to claim 1, wherein an insulating layer is mounted between the side portion of the electrical contact and the side surface.

4. The VCSEL according to claim 1, wherein the electrical contact extends from the side portion to an upper side of the main element.

5. The VCSEL according to claim 1, wherein side portions of the electrical contacts, which are configured as a cathode or as an anode, are mounted on a common side surface of the main element.

6. The VCSEL according to claim 1, wherein a chamfer or a rounded portion is formed at a transition portion between the side surface and the top surface, wherein a portion of the electrical contact is arranged on the transition portion.

7. The VCSEL according to claim 1, wherein a solder barrier is formed on the electrical contact on the top surface of the mesa portion and prevents solder from flowing from the side portion to the emission region.

8. The VCSEL according to claim 1, wherein the electrical contact is formed only on the side surface without extending to the top surface.

9. A VCSEL array, comprising at least two main elements according to claim 1, each of which has at least one side portion of a respective electrical contact on a side surface thereof.

10. An electrical circuit board having a VCSEL according to claim 1, wherein a side portion of the electrical contact of the VCSEL is arranged in a region of a conductor track of the electrical circuit board so that the side portion is capable of being soldered onto a solder contact of the electrical circuit board.

11. The electrical circuit board according to claim 10, wherein the side portion for a solder joint is oriented perpendicular to the conductor track and/or rests on the conductor track.

12. A method for producing a VCSEL according to claim 1, the method comprising:
arranging the main elements, each with a mesa portion, on a wafer,
forming a trench next to a respective main element, wherein the trench produces the side surface on the respective main element, wherein the side portion of the electrical contact is arranged on the side surface of the respective main element.

13. The method according to claim 12, wherein the trench is formed between two main elements, wherein the side surfaces are coated, wherein the two main elements are separated from one another by making a separating cut along the trench, wherein the separating cut leaves the side portions on the side surfaces.

14. The method according to claim 12, wherein the trench is completely filled with a metal, such that the side surface is also covered with the metal.

15. The method according to claim 14, wherein, after the trench is filled, a portion next to the trench which reaches to the trench is removed so that the mesa portion with the side surface covered with the metal is exposed so that the metal is capable of being contacted.
